(19) United States
(12) Patent Application Publication
(10) Pub. No.: US 2012/0231576 A1
(43) Pub. Date: Sep. 13, 2012

(54) Aerosol Jet (R) Printing System for Photovoltaic Applications

(75) Inventors: Bruce H. King, Albuquerque, NM (US); David H. Ramahi, Boston, MA (US)

(73) Assignee: OPTOMEC, INC., Albuquerque, NM (US)

(21) Appl. No.: 13/476,429

(22) Filed: May 21, 2012

Related U.S. Application Data
(62) Division of application No. 12/203,074, filed on Sep. 2, 2008.
(60) Provisional application No. 60/969,467, filed on Aug. 31, 2007.
(60) Provisional application No. 61/047,284, filed on Apr. 23, 2008.

(51) Int. Cl. H01L 31/18; B05B 1/00; B05D 1/36; B05D 1/02; B05D 5/12

(52) U.S. Cl. 438/98; 427/421.1; 427/115; 427/402; 427/286; 427/265; 118/300; 257/E31.111

(57) ABSTRACT

Method and apparatus for depositing multiple lines on an object, specifically contact and busbar metallization lines on a solar cell. The contact lines are preferably less than 100 microns wide, and all contact lines are preferably deposited in a single pass of the deposition head. There can be multiple rows of nozzles on the deposition head. Multiple materials can be deposited, on top of one another, forming layered structures on the object. Each layer can be less than five microns thick. Alignment of such layers is preferably accomplished without having to deposit oversized alignment features. Multiple atomizers can be used to deposit the multiple materials. The busbar apparatus preferably has multiple nozzles, each of which is sufficiently wide to deposit a busbar in a single pass.

### CROSS-REFERENCE TO RELATED APPLICATIONS

This application is a divisional application of U.S. patent application Ser. No. 12/203,074, entitled “Aerosol Jet® Printing System for Photovoltaic Applications”, filed on Sep. 2, 2008, which application claims the benefit of the filing of U.S. Provisional Patent Application Ser. No. 60/969,467, entitled “Aerosol Jet® Printing System for Photovoltaic Applications”, filed on Aug. 31, 2007, and U.S. Provisional Patent Application Ser. No. 61/047,284, entitled “Multi-Material Metallization”, filed on Apr. 23, 2008, the specifications of which are incorporated herein by reference.

### BACKGROUND OF THE INVENTION

1. Field of the Invention (Technical Field)

The present invention relates to the field of direct write printing of metallizations using an integrated system of single and multi-nozzle print heads, particularly directed towards collector lines and busbars for photovoltaic cell production.

2. Description of Related Art

Screen-printing is the most common technique in use today for the front side metallization of crystalline silicon solar cells. However, this approach is reaching its limit as the industry pushes for higher efficiency cells and thinner wafers. For example, cell efficiency can be improved by reducing the area on the wafer that is shadowed by the printed conductive lines. However, it becomes increasingly difficult to squeegee the ink through the mesh of the screen as the gap in the stencil is reduced. Screen stretch also becomes more of a problem, resulting in greater cost associated with screen waste. While advancements in screen print technology have pushed it beyond what was conventionally thought to be possible a decade ago, the limits to the feature sizes that are possible are rapidly approaching. Further, as thinner silicon wafers are introduced into production lines, waste due to wafer breakage becomes more significant due to the pressure that screen printing places on the wafer. There is a clear need for an alternative printing approach that addresses these limitations.

Further increases in efficiency have also been attempted by utilizing a two-layer structure for the collector lines. Traditionally, collector lines have been highly loaded with glass in order to form electrical contact with the underlying silicon. However, this high glass concentration increases the resistance and hence the current loss of the collector line. An optimized collector line would simultaneously make good electrical contact with the silicon and minimize resistance between the silicon and the busbar. A two-layer structure can accomplish this by decoupling the part of the collector that makes contact to the emitter from the part that carries the current. In an optimal structure, the thickness of the contact layer is only as thick as is required to form contact with the silicon, while the thickness of the current carrying layer is maximized to reduce ohmic losses. One approach to achieving this structure is to utilize plating of a pure conductor onto a seed layer. One such process for achieving this is the Light Induced Plating (LIP) process [A. Mette, C. Schetter, D. Wissen, et al, Proceedings of the IEEE 4^{th} World Conference on Photovoltaic Energy Conversion, Vol. 1, (2006) 1056]. Several possible approaches exist for printing seed layers for a subsequent plating step. Ink Jet offers a potential non-contact printing approach [C. J. Curtis, M. van Hest, A. Miedaner, et al, Proceedings of the IEEE 4^{th} World Conference on Photovoltaic Energy Conversion, Vol. 2, (2006) 1392]. However, it has several known limitations. Inks must be diluted, requiring multiple passes to build adequate thickness. Printing of commercial screen-printing pastes is not possible, necessitating the development of specialized nanoparticle or organometallic inks. Droplets are relatively large, resulting in line widths that are no better than those achievable by screen-printing. The gap between the substrate and the print head is critical, resulting in low tolerance to uneven substrates.

Increases in efficiency can also be achieved by utilizing back side metallization of crystalline silicon solar cells. The photovoltaic industry is experimenting with new backside print patterns and the printing of new materials, such as copper, nickel, alloys, and conductive coatings to improve overall cell efficiencies, while simultaneously moving to thinner wafers in an effort to reduce costs and/or increase operating income. Traditional screen print methods do not accommodate these future requirements.

### BRIEF SUMMARY OF THE INVENTION

The present invention is a method for maskless, noncontact printing of parallel lines on an object, the method comprising the steps of providing a deposition head; disposing a plurality of nozzles across the width of the deposition head, wherein the number of nozzles equals the number of lines to be printed; atomizing a first material to be deposited; ejecting the atomized first material from the nozzles; moving the deposition head relative to the object; and depositing a plurality of lines comprising the first material on the object; wherein each line is less than approximately 100 microns in width. Each line is preferably less than approximately 50 microns in width, and more preferably less than approximately 35 microns in width. The moving step optionally comprises rastering the deposition head. The object optionally comprises a solar cell of at least 156 mm in width, in which case the depositing step is preferably performed in less than approximately three seconds.

The disposing step optionally comprises arraying the nozzles in a single row or in multiple rows. In the latter case, the nozzles in a first row are optionally aligned with nozzles in a second row, which enables depositing additional material on top of previously deposited material. Such additional material is optionally different than the previously deposited material, in which case the step of atomizing the additional material is optionally performed using a dedicated atomizer. Alternatively, nozzles in a first row are offset from nozzles in a second row, thereby reducing the distance between deposited lines.

The method optionally comprises the steps of aligning the deposition head and the object, atomizing a second material, and depositing lines comprising the second material on top of the previously deposited lines comprising the first material, thereby forming a multiple layer deposit. The previously deposited lines and/or the lines comprising the second material are preferably less than approximately five microns thick. This method optionally further comprises the step of sequentially activating separate atomizer units, each atomizer corresponding to one of the first or second materials. This method is preferably performed without having to print oversized features to enable the aligning step. The step of depositing lines comprising the second material is preferably performed without first having to substantially dry the previously deposited lines.

The present invention is also an apparatus for maskless, noncontact deposition of busbars on a solar cell, the apparatus comprising a deposition head; one or more atomizers, each atomizer comprising one or more atomizing actuators; at least one nozzle comprising a tip sufficiently wide to deposit a busbar without rastering. The apparatus optionally comprises one atomizer for every eight to twelve nozzles. The apparatus preferably comprises a virtual impactor, which optionally comprises rectangular geometry. The apparatus preferably comprises a sufficient number of nozzles to simultaneously deposit all of the required busbars.

An advantage of the present invention is the ability to reduce the width and thickness of seed layers for collector lines on solar cells.

Objects, advantages and novel features, and further scope of applicability of the present invention will be set forth in part in the detailed description to follow, taken in conjunction with the accompanying drawing, and in part will become apparent to those skilled in the art upon examination of the following, or may be learned by practice of the invention. The objects and advantages of the invention may be realized and attained by means of the instrumentalities and combinations particularly pointed out in the appended claims.

### BRIEF DESCRIPTION OF THE SEVERAL VIEWS OF THE DRAWINGS

The accompanying drawings, which are incorporated into and form a part of the specification, illustrate one or more embodiments of the present invention and, together with the description, serve to explain the principles of the invention. The drawings are only for the purpose of illustrating one or more preferred embodiments of the invention and are not to be construed as limiting the invention. For purposes of clarity and comprehension thereof similar features between different embodiments will ordinarily be described with like reference numerals. In the drawings:

FIG. 1 is an isometric schematic of a single print head with multiple print nozzles;

FIG. 2A is a schematic showing the side and bottom view of a single row of nozzles;

FIG. 2B is a schematic of a print head showing the side and bottom view of a trailing row of nozzles aligned with the leading row of nozzles;

FIG. 2C is a schematic of a print head showing the side and bottom view of a trailing row of nozzles offset from the leading row of nozzles;

FIG. 3 is an isometric schematic of the busbar print head;

FIG. 4 is a schematic showing the bottom view of a rectangular nozzle for busbar printing;

FIG. 5 is a schematic showing the bottom view of a wide area nozzle print head capable of printing the entire surface of a solar cell;

FIG. 6 is schematic showing the bottom view of a busbar print head showing a multinozzle array;

FIG. 7A is a schematic of an isometric assembly showing four atomizers; and

FIG. 7B is a schematic of an isometric busbar print head with one atomizer.

### DETAILED DESCRIPTION OF THE INVENTION

The present invention generally relates to apparatuses and methods for high-resolution, maskless printing of liquid and liquid-particle suspensions using aerodynamic focusing for metallization applications. In the most commonly used embodiment, an aerosol stream is focused and printed onto a planar or non-planar target, forming a pattern that is thermally or photochemically processed to achieve physical, optical, and/or electrical properties near that of the corresponding bulk material. This process is called M³D® (Maskless Mesoscale Material Deposition) technology, and is used to print aerosolized materials with linewidths that can be an order of magnitude smaller than lines printed with conventional thick film processes. Printing is performed without the use of masks. Further, the M³D® process is capable of defining lines having widths smaller than 1 micron.

The M³D® apparatus preferably uses an Aerosol Jet® print head to form an annularly propagating jet composed of an outer sheath flow and an inner aerosol-laden carrier flow. In the annular aerosol jetting process, the aerosol stream enters the print head, preferably either directly after the aerosolization process or after passing through a heater assembly, and is directed along the axis of the device towards the print head orifice. The mass throughput is preferably controlled by an aerosol carrier gas mass flow controller. Inside the print head, the aerosol stream is preferably collimated by passing through a millimeter-size orifice. The emergent particle stream is then preferably combined with an annular sheath gas, which functions to eliminate clogging of the nozzle and to focus the aerosol stream. The carrier gas and the sheath gas most commonly comprise dry nitrogen, compressed air or an inert gas, where one or all may be modified to contain solvent vapor. For example, when the aerosol is formed from an aqueous solution, water vapor may be added to the carrier gas or the sheath gas to prevent droplet evaporation.

The sheath gas preferably enters through a sheath air inlet below the aerosol inlet and forms an annular flow with the aerosol stream. As with the aerosol carrier gas, the sheath gas flowrate is preferably controlled by a mass flow controller. The combined streams exit the nozzle at a high velocity (˜50 m/s) through an orifice directed at a target, and subsequently impinge upon it. This annular flow focuses the aerosol stream onto the target and allows for printing of features with dimensions smaller than approximately 1 micron. Printed patterns are created by moving the print head relative to the target.

### Front-Side Metallization of Solar Cells

Traditional screen-printed solar cells are fabricated with a front-side metallization pattern that is comprised of many narrow collector lines (ca. 100-150 microns wide) and several busbars that are much larger (ca. 2 mm wide). A typical 156 mm×156 mm wafer consists of between 60 and 80 collector lines and two or three busbars. Such a cell will have a conversion efficiency of about 15%, about half the theoretical maximum. Improvements in efficiency of only a fraction of a percent are significant and increase the total power output of the cell over its expected lifetime of 20-30 years. It has long been recognized that reducing the width of the collector lines reduces the shadowed area of the cell and improves its efficiency. Screen-printing faces many challenges in this regard, with 100 microns being considered by many to be the lowest practical limit in a manufacturing setting. A further improvement in efficiency is possible by reducing the series resistance of the collector lines and busbars, which conduct the generated electricity out to the cell. However, traditional screen-printing pastes contain a large amount of glass frit, which is required to form an electrical contact to the underlying doped silicon. While necessary, the glass frit increases series resistance of the collector lines and busbars.

Recently, Aerosol Jet Printing has been applied to produce efficient silicon solar cells by first printing a commercial screen-printing paste, followed by the Light-Induced Plating (LIP) process [A. Mette, P. L. Richter, S. W. Glunz, et al, 21st European Photovoltaic Solar Energy Conference, 2006, Dresden]. A single nozzle Aerosol Jet printing system was used to print a seed layer with good mechanical contact and low contact resistance. LIP was then used to plate a thick conductive trace with low series resistance. The cells produced by this approach had efficiencies as high as 16.4%.

The ability to print collector lines with greatly reduced widths combined with the opportunity to reduce series resistance by materials optimization, gives Aerosol Jet Printing a significant advantage over screen-printing in the rush to improve solar cell efficiency. Further improvements in efficiency are also possible by printing the busbars in a separate step from the collector lines. In this way, the series resistance of the busbars can be optimized independently of the collector lines. Conversely, the contact resistance of the collector lines to the underlying silicon can be optimized independently of the busbars.

Other advantages of Aerosol Jet Printing can be realized in a manufacturing setting. For example, Aerosol Jet Printing is a non-contact method and as such, no pressure is placed on the relatively fragile wafers. This is in contrast to screen-printing in which the screen is forced into contact with the wafer as the squeegee forces paste through the openings in the screen. In addition to the downward forces, the wafer is also subjected to upward forces as the paste releases from the screen during the removal step. At this point in the process, waste due to wafer breakage can be as high as several percent of the number of wafers input to the system. While not directly affecting cell efficiency, waste lowers overall power output from a cell manufacturing line. A further improvement over screen-printing relates to cost of ownership; screens are subject to stretching, tearing, and clogging and must be replaced on a regular basis. Direct printing eliminates costs associated with screen replacement.

To move Aerosol Jet Printing into solar cell manufacturing, multi-nozzle print heads based on existing single-nozzle technology have been developed. These print heads are purpose-built for printing narrow collector lines and building up collector line heights through the use of in-line nozzles. Additionally, single nozzle print heads have been developed for printing busbars. While based on existing single nozzle technology, these print heads differ significantly in that they are designed to print features several millimeters wide in a single print pass. Both of these innovations enable printing of solar cells at useful manufacturing speeds. The current print system is capable of printing both seed layers and fully functioning collector lines for the front side metallization for a single 156 mm×156 mm solar cell in 3 seconds, which is comparable to the speed of a screen printer.

Thus, the present invention relates to an apparatus and method for the metallization of solar cells, in particular, collector lines and busbars, using the M³D® Aerosol Jet® process with a single and multi-nozzle integrated system. This invention may equally be applied to either printing seed layers for subsequent plating operations or direct printing of fully functioning conductive collector lines and busbars dependent on specific customer process requirements. The present invention may also have utility for other types of solar cell manufacturing besides traditional front-side metallization, such as thin-film and flex PV metallization. Although the bulk of this discussion is aimed at metallization, the process is also capable of printing organic and inorganic non-metallic compositions. Further, the present invention may be used in coating applications and other similar processes.

### Multi-Nozzle Print Head

The multi-nozzle print head is primarily used in the fabrication of collector lines in a commercially viable manner. As cells grow larger (e.g. from 156 mm×156 mm to 210 mm×210 mm) and collector lines width shrinks, the total number of collector lines per wafer is increasing significantly. While it is possible to print a full wafer using a single Aerosol Jet nozzle, the time required to do so precludes the use of this technology in a manufacturing setting. The only economically feasible means is to print multiple collector lines simultaneously. This could also be done using multiple but separate single nozzle Aerosol Jet Print Heads. However, only modest increases in production speed are possible by this approach due to the relatively small pitch between collector lines and the relatively large spacing between individual print heads.

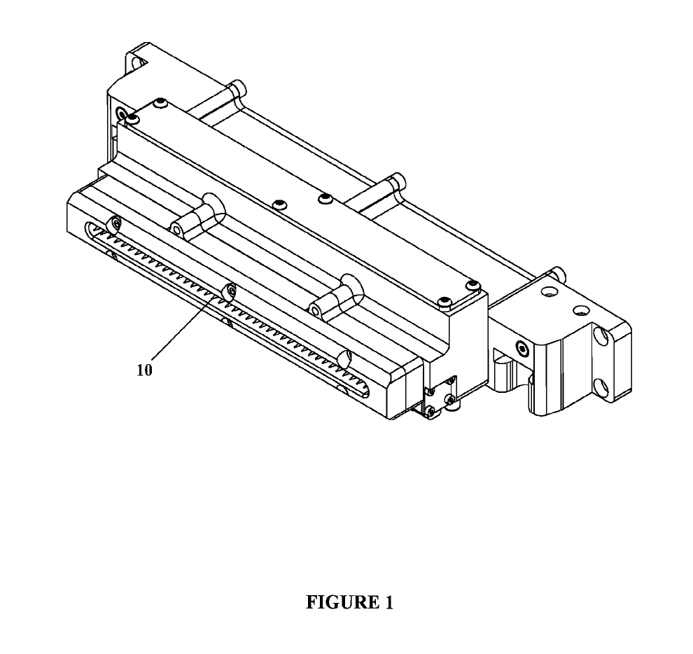

A more useful approach incorporates multiple print nozzles into a single print head, thus minimizing the spacing between nozzles 10, as shown in FIG. 1. Using this approach, it is possible to print substantially all of the collector lines simultaneously. However, multiple printing passes may be used to print the collector lines. Collector lines may be printed in contiguous blocks, in an interdigitated fashion, or in a combination of the two.

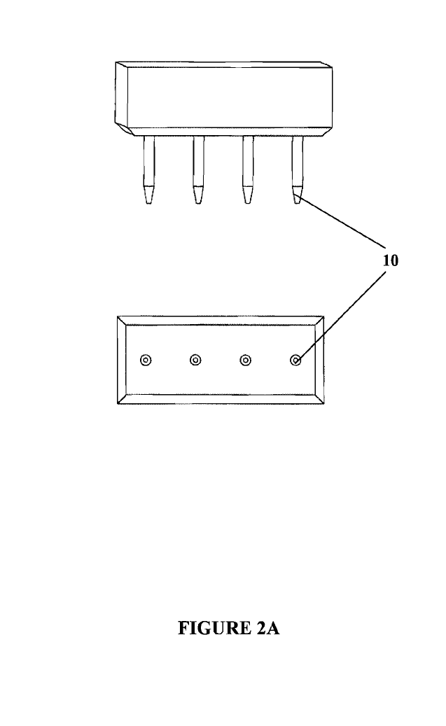

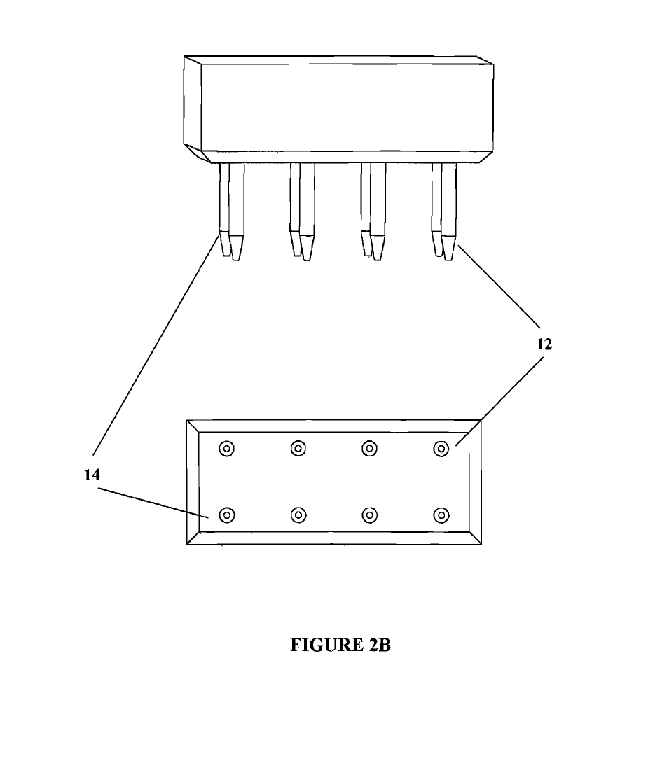

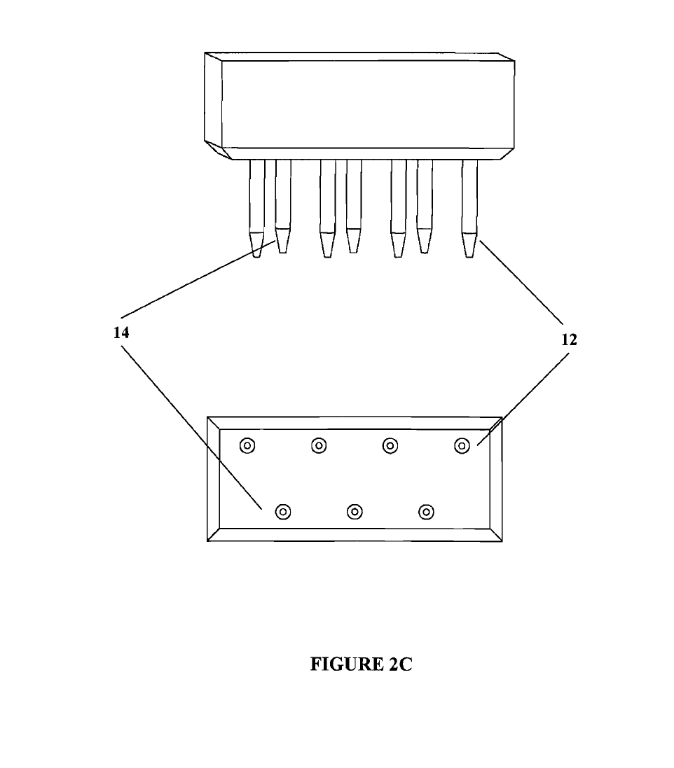

In one embodiment, all nozzles 10 are arrayed in a single row, as shown in FIG. 2A. Nozzle spacing may be equal to or an integer multiple of the desired collector line spacing. In the first case, collector lines may be printed in a single step, while in the latter case multiple print steps are required. In another embodiment, nozzle spacing is a non-integer multiple of desired collector line spacing. In this case, the print head must be rotated relative to the wafer and print direction, such that the projected nozzle spacing is equal to or an integer multiple of the desired collector line spacing.

In another embodiment, the nozzles are arrayed in multiple rows, such that the print head consists of a leading row of nozzles followed by one or more trailing rows of nozzles. Nozzles in trailing rows 14 may be aligned with the nozzles in the leading row 12 (as shown in FIG. 2B) or optionally offset (as shown in FIG. 2C). In the first case, nozzles in trailing rows 14 print on top of collector lines printed by the leading row 12 of nozzles, thus resulting in thicker collector lines. In the second case, nozzles in trailing rows 14 print collector lines that are offset from those printed by the leading row 12 of nozzles. The nozzle offset preferably matches desired collector line spacing.

The collector line width can be adjusted over a wide range to accommodate different cell designs. However, the greatest utility is found when printing line widths that cannot be achieved by screen-printing. The line widths are preferably less than approximately 50 microns and more preferably less than approximately 35 microns. It should be recognized that these line widths serve only as a guide to what may be useful for printing solar cells; Aerosol Jet technology is capable of printing line widths approximately smaller than 1 micron. The useful printed line width for a solar cell may be controlled by factors that are beyond the control of Aerosol Jet printing. These factors include surface roughness of the wafer due to texturization and interactions between the ink and substrate.

The collector lines are typically substantially straight and parallel. However in the most general case, the collector lines may be printed in an arbitrary pattern as desired to increase solar cell efficiency. No limitation is made with regard to the specific pattern that may be printed.

In one embodiment the invention is used to print a seed layer for subsequent plating, such as through the Light Induced Plating process. Collector lines may also be printed directly through one or more printing steps.

One or more materials may be printed using the invention, either in the same location or in differing locations. Printing in the same location allows composite structures to be formed, whereas printing in different areas allows multiple structures to be formed on the same layer of a substrate. The invention does not depend on any specific material formulation.

### Busbar Print Head

The Busbar Print Head apparatus is used primarily in the fabrication of busbars in a commercially viable manner. The requirements for busbars are significantly different than those for collector lines as the former are generally significantly wider, approximately 2 mm wide vs. approximately 50 microns. A conventional single nozzle M³D® print head can be used to print busbars; however, it requires rastering many times to reach the needed width. This method is time consuming and a need exists for a print head with a throughput comparable to that possible with a multi-nozzle print head used to print collector lines.

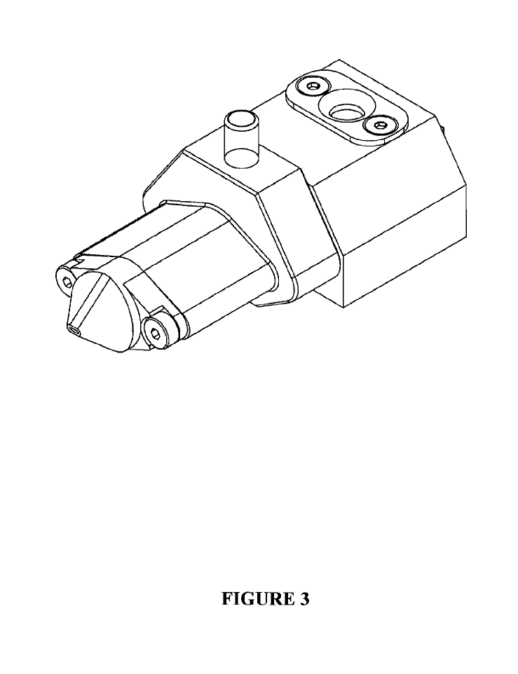

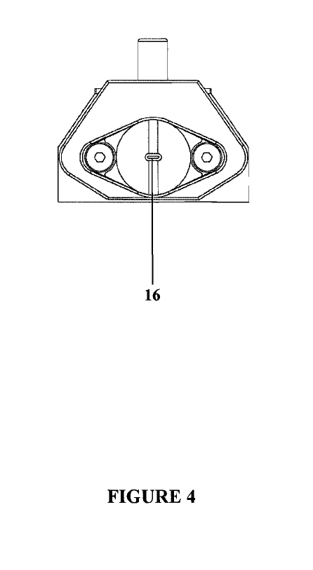

The principles of operation for the Busbar Print Head apparatus generally resemble the conventional M³D® single nozzle print head; however, the internal geometry is increased significantly to facilitate printing of a much wider trace than is typically possible with a conventional single nozzle print head as shown in FIG. 3. A further improvement is the use of a rectangular nozzle 16, which in principle can be used to scale the width of the printed line to any desired width, as shown in FIG. 4. An advantage of the rectangular nozzle is the fabrication of increased thickness of a printed feature when the deposition head travels in the direction of the shorter sides (thus depositing a narrower line), because it is depositing more material over itself. This is also true of the broad area coverage nozzle.

Printed busbar linewidths typically fall within the range of 1-2 mm, but can be smaller as cell design improves; the width of the busbar is determined by the solar cell design and is not limited by the invention. The printed busbar width can be adjusted over a wide range to accommodate different cell designs.

More than one Busbar Print Head apparatus can be used in order to simultaneously print more than one busbar. In one embodiment of such a configuration, the sheath gas and aerosol delivery lines are split between a number of separate single nozzle apparatuses. In another embodiment, the geometry for printing the busbars may be incorporated into a single device, forming a multinozzle array. Such an array differs from the arrays previously described for printing collector lines primarily in the size and geometry of the components.

All of the busbars are preferably printed simultaneously. However, multiple printing steps may be used to print the busbars.

The busbars are typically substantially straight and parallel. However, they may be printed in an arbitrary pattern as desired to increase solar cell efficiency. No limitation is made with regard to the specific pattern that may be printed.

An embodiment of the present invention is used to print a seed layer for subsequent plating, such as through the Light Induced Plating process. Busbars may also be printed directly through one or more printing steps.

One or more materials may be printed using the invention, either in the same location or in differing locations. Printing in the same location allows composite structures to be formed, whereas printing in different areas allows multiple structures to be formed on the same layer of a substrate. The invention does not depend on any specific material formulation.

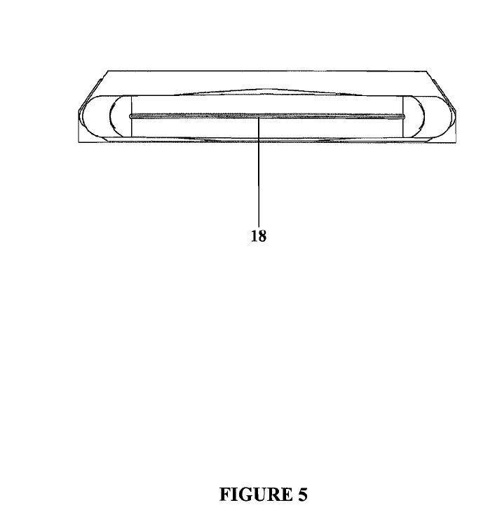

The concepts of the Busbar Print Head may be scaled to facilitate printing over a relatively large area, including the entire surface of the solar cell, using a wide area nozzle 18, as shown in FIG. 5. This apparatus can be used for example to print an aluminum back side metallization layer or a passivation layer for either the front or back sides of the wafer.

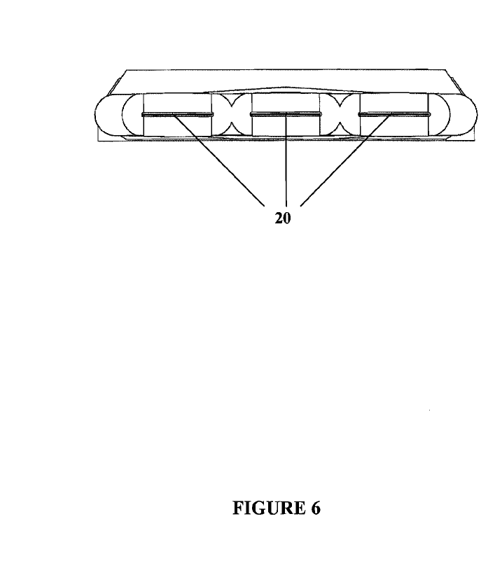

In one embodiment, the geometry for printing the busbars may be incorporated into a single device, forming a multinozzle array 20, as shown in FIG. 6. Such an array differs from the arrays previously described for printing collector lines primarily in the size and geometry of the components. The individual nozzles in this array may be spaced to facilitate full print coverage with a minimal number of print steps. In the most general case, the print head consists of a single, wide nozzle capable of covering the entire surface in a single print step.

This device finds utility in application areas other than printed solar cells. For example, such a device may be used to print catalyst layers for polymer electrode membrane (PEM) fuel cells.

### Atomizers

Aerosol Jet print heads generally can use one or more atomizers of varying design. However, the print heads described as part of this invention generally require a greater quantity of aerosolized ink than is typically generated by the conventional atomizers used for single nozzle Aerosol Jet printing. This requirement is addressed by integrating multiple atomizing elements into the design. For example, multiple ultrasonic transducers can be incorporated into an ultrasonic atomizer. Likewise, increasing the number of atomizing jets in the design increases pneumatic atomizer output.

In one embodiment, multiple atomizing units, each comprising one or more atomizing elements, generate aerosol for a single print head. In another embodiment, a single atomizing unit comprising one or more atomizing elements generates aerosol for a single print head. In either embodiment, the print head may be a multinozzle design or alternatively a busbar or wide area coverage design.

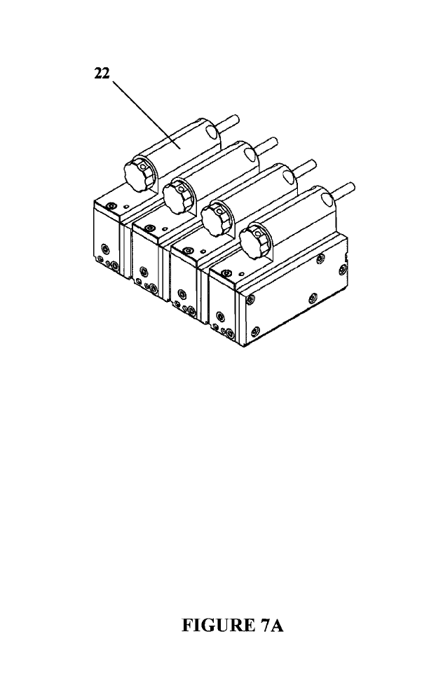

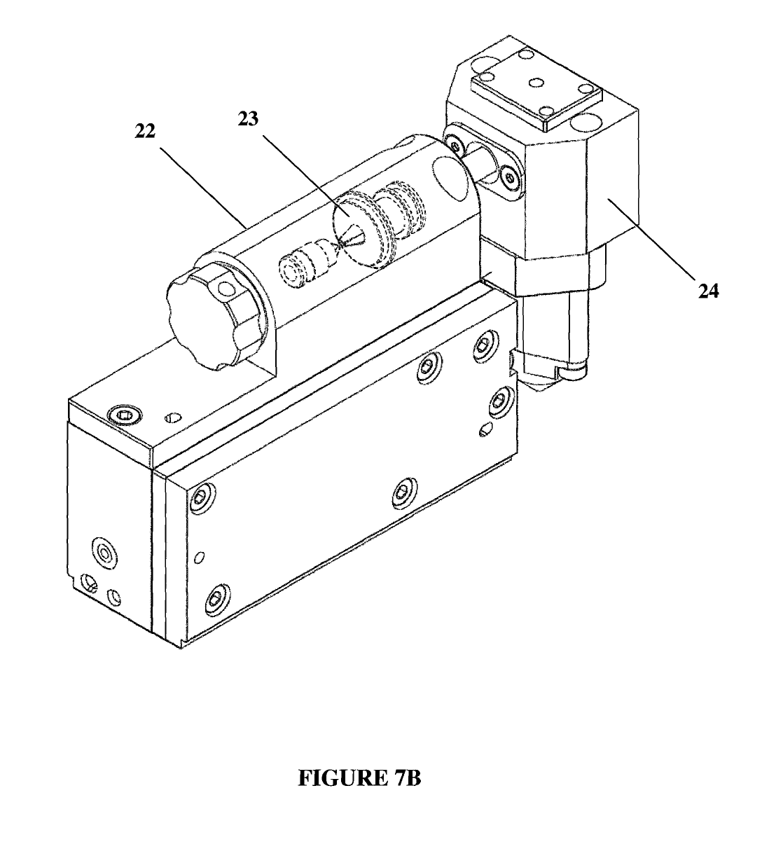

A multinozzle print head preferably comprises one atomizing unit comprising one atomizing element for each group of 8-12 nozzles, or more. For example, a 40-nozzle print head may be configured with 4 atomizing units 22, as shown FIG. 7A. A single busbar print head 24 preferably comprises one atomizing unit 22 comprising two atomizing elements and virtual impactor 23, as shown in FIG. 7B. For example, a busbar array configured to print three busbars simultaneously would preferably three individual busbar heads, each of which may have its own atomizing unit, or utilize one atomizer server for all three busbar heads.

The atomizing elements preferably comprise Collison pneumatic atomizers. Pneumatic atomizers use large quantities of compressed gas as the energy source to atomize the fluid. The quantity of gas required is generally too great to be passed through the relatively small nozzles used to focus the aerosol without creating turbulent flow and destroying the focused, collimated aerosol jet. Simply venting the excess gas reduces system output by reducing the quantity of aerosolized material available for printing. Thus a virtual impactor is preferably used to simultaneously reduce the flowrate and concentrate the aerosol. The virtual impactor preferably comprises a circular jet and collector. However, fluid dynamic constraints coupled with the small droplet diameter of the aerosol that is typically generated with the pneumatic atomizer impose an upper limit on the jet diameter. As this limit is approached and exceeded, the efficiency of the impactor gradually decreases to the point where most of the useful aerosol is vented from the system rather than being printed. Multiple virtual impactors with circular geometry may alternatively be integrated into a single atomizing unit.

In another embodiment, a virtual impactor with rectangular geometry may be used in place of circular geometry. Rectangular geometry can be adjusted such that the fluid dynamic constraints are controlled by the short direction of the virtual impactor and small droplets are retained in the process gas stream rather than being vented and wasted. Gas throughput scales approximately linearly with the length of the virtual impactor in the long direction. This embodiment has the potential to simultaneously facilitate greater output while reducing system complexity. This aspect of the invention may be used with all three of the print heads described above.

### Multi-Material Metallization

Using a single or multi-jet array in an M³D system, multiple materials are deposited in order to create multi-material collector lines and/or multi-material busbars for use in solar cell applications. The approach allows for a collector line to be comprised of two or more materials such that different parts of the collector line (i.e.: base, middle, top, ends, etc.) can be locally optimized to serve discrete functions (i.e.: adhesion, contact resistance, conductivity, encapsulation, dopants, etc.). Similarly, the busbars can be constructed with the same or differing material make-ups to provide localized optimization (i.e.: base, middle, top, ends, etc.) for target functions (i.e.: adhesion, conductivity, solderability, encapsulation, etc.). As one example, the system can build a collector line by first printing a silver/glass screenprinting material optimized for fire-through and contact resistance as a base layer, directly followed by a pure silver nanoparticle material top layer for enhanced conductivity. In another embodiment, multiple material compositions can be printed in spatially separated locations. Multiple collector line compositions can be printed, as well as separate compositions for collector lines and busbars.

Multi-material structures can be printed on the same or different print systems. In the first case, two or more atomization units, each containing an ink of different composition, feed a single print head. The appropriate atomization unit is selected to print the desired layers in the desired sequence. In the second case, individual print systems are configured for a single material and multiple print systems are arranged in series. Wafers travel through the line from one system to the next. In this case, the sequence in which layers are printed is predetermined by the order of the systems in the line. When moving between print systems, wafers are realigned to the new system to ensure that the new layer is aligned properly to the previous layer.

This invention has several advantages over screen-printing, which is the current state of the art used in production for the printing of collector lines and busbars for solar cells, most typically using the same singular material to make-up the entirety of the collector lines and busbars. The first advantage of M³D printing is that ink is printed via a nozzle rather than a screen. Alignment to preexisting features on the wafer is possible since the location of the fixed nozzle is known. In contrast, a new screen-printing screen begins to stretch immediately after it is installed and continues to stretch throughout its lifetime. Alignment between subsequent layers is typically achieved by printing oversize features (such as contact pads) so that random misalignment due to screen stretch can be overcome. This approach is in direct contrast to the push in the photovoltaics industry for ever-decreasing line widths. Second, M³D printing is capable of printing layers as thin as 0.5 micron or less, whereas screen-printing is limited to approximately 5 microns. This gives the M³D technology greater flexibility to optimize the ratio between top, middle and bottom layers. An additional advantage of M³D printing is that subsequent layers can often be applied immediately, without an intermediate drying step. Finally, M³D printing is a completely non-contact printing approach, meaning that the process of applying subsequent layers does not disturb previous layers.

Although the invention has been described in detail with particular reference to these preferred embodiments, other embodiments can achieve the same results. Variations and modifications of the present invention will be obvious to those skilled in the art and it is intended to cover in the appended claims all such modifications and equivalents. The entire disclosures of all references, applications, patents, and publications cited above are hereby incorporated by reference.

What is claimed is:

1. A maskless, noncontact method for depositing material, the method comprising:
atomizing a material to form an aerosol;
surrounding the aerosol with a sheath gas to form a combined flow;
passing the combined flow through one or more non-circular nozzles;
forming a flow of material having a non-circular cross section; and
depositing the non-circular flow of material onto a substrate.

2. The method of claim 1 wherein the deposited material comprises a structure selected from the group consisting of metallization for a photovoltaic solar cell, a catalyst layer for a fuel cell, a thin film solar cell layer, and a coating.

3. The method of claim 1 wherein at least one of the nozzles is sufficiently wide to coat a solar cell in a single pass.

4. The method of claim 1 wherein the solar cell is at least 156 mm in width.

5. The method of claim 4 wherein the depositing step is performed in less than approximately three seconds.

6. The method of claim 1 further comprising the step of depositing additional material on top of previously deposited material.

7. The method of claim 1 wherein a plurality of nozzles is arranged in an array comprising a plurality of rows, and further comprising the steps of:
translating the array in a direction perpendicular to the rows during deposition; and
forming a plurality of parallel lines of the material.

8. The method of claim 7 further comprising the steps of:
nozzles in a first row depositing a first material; and
nozzles in a second row aligned with the first row depositing a second material on top of the first deposited material during the translating step.

9. The method of claim 7 wherein nozzles in a first row are offset from nozzles in a second row with respect to the translation direction; and further comprising the step of depositing parallel lines having a distance between them smaller than a distance between nozzles in one of the rows.

10. The method of claim 7 wherein the parallel lines comprise busbars or collector lines on a solar cell.

11. The method of claim 10 further comprising simultaneously depositing all of a required number of busbars and/or collector lines in one pass.

12. The method of claim 1 wherein the non-circular cross section comprises a major axis or long side, and further comprising the steps of:
translating the nozzle in a direction parallel to the major axis or long side; and
depositing a first line of material that is narrower and thicker than a second line of material deposited during translation of the nozzle in a perpendicular direction.

13. A method for printing a deposit comprising different materials, the method comprising the steps of:
surrounding an aerosol comprising a first material with a sheath gas to form a first combined flow;
passing the first combined flow through a first nozzle;
depositing the first material;
surrounding an aerosol comprising a second material with a sheath gas to form a second combined flow;
passing the second combined flow through the first nozzle or a second nozzle; and
depositing the second material on top of the previously deposited first material, thereby forming a multiple layer deposit.

14. The method of claim 13 wherein the nozzles are non-circular.

15. The method of claim 13 wherein the second nozzle is the same nozzle as the first nozzle.

16. The method of claim 13 further comprising atomizing the first and second materials using a separate atomizer for each material.

17. The method of claim 16 further comprising sequentially activating the separate atomizers.

18. The method of claim 13 wherein the step of depositing the second material is performed without printing oversized alignment features or drying the previously deposited first material.

19. The method of claim 13 wherein the multiple layer deposit comprises a collector line or a busbar for a solar cell.

20. The method of claim 19 wherein the first deposited material comprises a contact layer or base layer.

21. The method of claim 19 wherein the first material comprises a silver/glass composition and the second material comprises a silver nanoparticle composition.

22. The method of claim 19 wherein each material is chosen for different optimal characteristics.

23. An apparatus for maskless non-contact deposition of at least one material for a solar cell, the apparatus comprising:
one or more atomizers for generating at least one aerosol comprising said at least one material;
one or more chambers for surrounding the at least one aerosol with a sheath gas;
one or more collector deposition heads for printing collector lines, each said collector deposition head comprising one or more collector nozzles; and
one or more busbar deposition heads for printing busbars, each said busbar deposition head comprising one or more busbar nozzles, each said busbar nozzle being sufficiently wide to deposit a busbar without rastering of said busbar deposition head.

24. The apparatus of claim 23 wherein one or more of said nozzles is non-circular.

25. The apparatus of claim 23 comprising a sufficient number of nozzles to simultaneously deposit all of a required number of busbars and/or collector lines in one pass.

26. The apparatus of claim 23 comprising separate atomizers for different materials.

27. The apparatus of claim 23 wherein said collector nozzles comprise a collector print head and said busbar nozzles comprise a busbar print head.

28. A method for maskless, non-contact deposition of one or more materials for a solar cell, the method comprising the steps of:
atomizing a first material into a first aerosol;
surrounding the first aerosol with a sheath gas to form a first combined flow;
ejecting the first combined flow through a plurality of first nozzles;
atomizing a second material into a second aerosol;
surrounding the second aerosol with a sheath gas to form a second combined flow;
ejecting the second combined flow through a plurality of second nozzles, each of the second nozzles sufficiently wide to deposit a busbar line without rastering;
moving the first nozzles relative to a substrate;
depositing collector lines on the substrate;
moving the second nozzles relative to the substrate; and
depositing busbar lines on the substrate.

29. The method of claim 28 further comprising the step of depositing a third material on top of the collector lines or the busbar lines.
